(19) United States
(12) Patent Application Publication
(10) Pub. No.: US 2024/0258420 A1
(43) Pub. Date: Aug. 1, 2024

(54) SEMICONDUCTOR DEVICE

(71) Applicant: Yi-Xuan LI, Taipei City (TW)

(72) Inventors: Yi-Xuan LI, Taipei City (TW); Kung-Yen LEE, Taipei City (TW); Ruei-Ci WU, Yuanlin City (TW)

(73) Assignee: Yi-Xuan LI, Taipei City (TW)

(21) Appl. No.: 18/415,341

(22) Filed: Jan. 17, 2024

(30) Foreign Application Priority Data
Jan. 30, 2023 (TW) 112103121

(51) Int. Cl. H01L 29/78; H01L 29/06

(52) U.S. Cl. CPC H01L 29/7811; H01L 29/0607; H01L 29/0696

(57) ABSTRACT

A semiconductor device includes a substrate, a main body, and an electrode unit. The main body is disposed on the substrate, and includes a cell region, an edge termination region surrounding the cell region, and an oxide insulation layer disposed on the cell region and the edge termination region so as to be spaced apart from the substrate. The cell region includes a first p-well region. The edge termination region includes a p-type extension unit adjacent to the first p-well region, an outer surrounding region surrounding the p-type extension unit, and a p-type doping region extending from the first p-well region toward the p-type extension unit. The electrode unit includes a source electrode disposed on the oxide insulation layer, a drain electrode disposed on the substrate opposite to the main body, and a gate electrode disposed in the oxide insulation layer and corresponding in position to the cell region.

### CROSS-REFERENCE TO RELATED APPLICATION

This application claims priority to Taiwanese Invention Patent Application No. 112103121, filed on Jan. 30, 2023, and incorporated by reference herein in its entirety.

### FIELD

The disclosure relates to a semiconductor device, and more particularly to a semiconductor device including an edge termination region.

### BACKGROUND

A conventional power transistor has a structure which mainly includes a cell region and an edge termination region that surrounds the cell region, where a depth and a doping concentration of the edge termination region are two crucial factors that determine whether the power transistor is capable of withstanding high voltage. However, when conducting a variety of doping processes or altering structural design in the edge termination region, additional photolithography and manufacturing steps are often required.

### SUMMARY

Therefore, an object of the disclosure is to provide a semiconductor device including an edge termination region that can alleviate at least one of the drawbacks of the prior art.

According to the disclosure, the semiconductor device includes a substrate, a main body, and an electrode unit. The main body is disposed on the substrate, and includes a cell region, an edge termination region that surrounds the cell region, and an oxide insulation layer that is disposed on the cell region and the edge termination region so as to be spaced apart from the substrate. The cell region includes a first p-well region. The edge termination region includes a p-type extension unit that is adjacent to the first p-well region, an outer surrounding region that surrounds the p-type extension unit, and a p-type doping region that extends from the first p-well region toward the p-type extension unit. The electrode unit includes a source electrode that is disposed on the oxide insulation layer, a drain electrode that is disposed on the substrate opposite to the main body, and a gate electrode that is disposed in the oxide insulation layer and that corresponds in position to the cell region.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a first embodiment of a semiconductor device according to the disclosure.

FIG. 2 is a line graph illustrating a simulation relationship between a breakdown voltage and a predetermined concentration ratio of a doping concentration of a p-type junction termination extension (JTE) region to a doping concentration of an outer surrounding region of the first embodiment of the semiconductor device according to the disclosure.

FIG. 3 is a schematic view illustrating a second embodiment of the semiconductor device according to the disclosure.

FIG. 4 is a line graph illustrating a simulation relationship between a breakdown voltage and a predetermined concentration ratio of a doping concentration of each of the p-type JTE region and p-type JTE rings to a doping concentration of the outer surrounding region of the second embodiment of the semiconductor device according to the disclosure.

FIG. 5 is a schematic view illustrating a third embodiment of the semiconductor device according to the disclosure.

FIG. 6 is a line graph illustrating a simulation relationship between a breakdown voltage and a predetermined concentration ratio of a doping concentration of each of the p-type JTE region and the p-type JTE rings to a doping concentration of the outer surrounding region of the third embodiment of the semiconductor device according to the disclosure.

FIG. 7 is a schematic view illustrating a fourth embodiment of the semiconductor device according to the disclosure.

FIG. 8 is a line graph illustrating a simulation relationship between a breakdown voltage and a predetermined concentration ratio of a doping concentration of each of the p-type JTE region and the p-type JTE rings to a doping concentration of the outer surrounding region of the fourth embodiment of the semiconductor device according to the disclosure.

FIG. 9 is a schematic view illustrating a fifth embodiment of the semiconductor device according to the disclosure.

FIG. 10 is a line graph illustrating a simulation relationship between a breakdown voltage and a predetermined concentration ratio of a doping concentration of each of the p-type JTE region and the p-type JTE rings to a doping concentration of the outer surrounding region of the fifth embodiment of the semiconductor device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “on,” “downwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

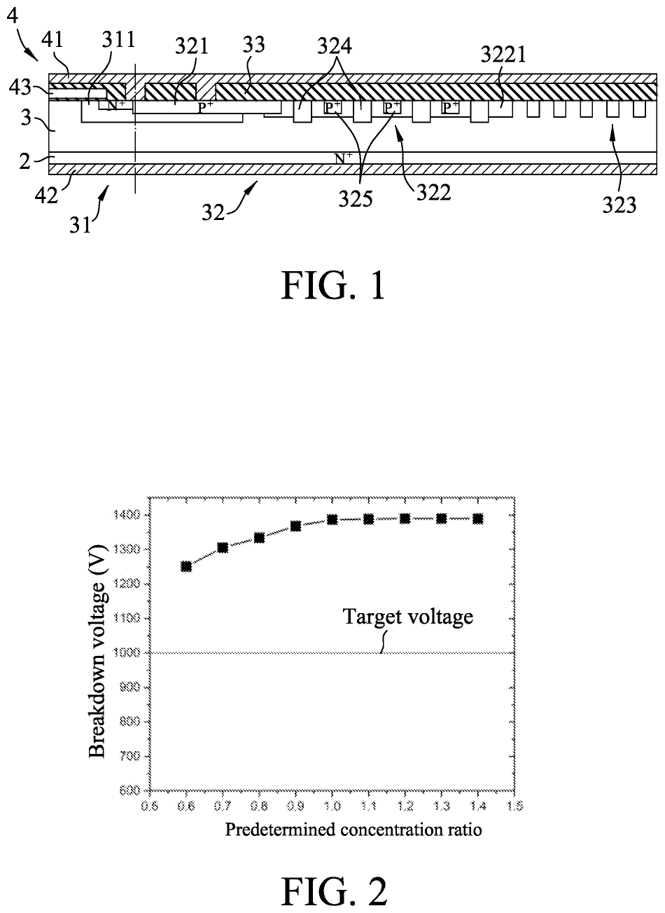

Referring to FIGS. 1 and 2, a first embodiment of a semiconductor device according to the disclosure includes a substrate 2, a main body 3, and an electrode unit 4.

Specifically, in this embodiment, the substrate 2 is an n-doped semiconductor substrate. The main body 3 is disposed on the substrate 2, and includes a cell region 31, an edge termination (ET) region 32 that surrounds the cell region 31, and an oxide insulation layer 33 that is disposed on the cell region 31 and the edge termination region 32 so as to be spaced apart from the substrate 2. The electrode unit 4 has electrodes disposed either on the substrate 2 or on the oxide insulation layer 33.

To be specific, in this embodiment, the cell region 31 includes a first p-well region 311, and the edge termination region 32 includes a p-type doping region 321, a p-type extension unit 322, an outer surrounding region 323, a plurality of p-well rings 324, and a plurality of p-plus rings 325.

In detail, the p-type doping region 321 extends from the first p-well region 311 toward the p-type extension unit 322. The p-type extension unit 322 is adjacent to the first p-well region 311, and the outer surrounding region 323 surrounds the p-type extension unit 322. In this embodiment, the p-type extension unit 322 includes a p-type junction termination extension (JTE) region 3221. In addition, the p-well rings 324 and the p-plus rings 325 are alternately disposed in the p-type extension unit 322 and specifically in the p-type junction termination extension region 3221, and the p-well rings 324 protrude from the p-type junction termination extension region 3211, so as to extend an electric field further downwardly.

The electrode unit 4 includes a source electrode 41 that is disposed on the oxide insulation layer 33, a drain electrode 42 that is disposed on the substrate 2 opposite to the main body 3, and a gate electrode 43 that is disposed in the oxide insulation layer 33 and that corresponds in position to the cell region 31.

In a conventional semiconductor manufacturing process, p-type doping is carried out in an n-type semiconductor, and a further photolithography process is necessary to allow p-type dopants to form p-type columns. In contrast, in the present disclosure, p-type doping can be performed in a p-type semiconductor such that p-type columns are directly formed therein, and doping of the edge termination region 32 and doping of the cell region 31 can be carried out simultaneously, thereby reducing the number of times required to conduct photolithography, so as to improve yield.

Specifically, in the first embodiment, the first p-well region 311 of the cell region 31 and the p-well rings 324 of the edge termination region 32 are formed using a same photomask, the p-type doping region 321 and the p-plus rings 325 are formed using another photomask of the same type, and the p-type junction termination extension region 3221 and the outer surrounding region 323 are formed using still another photomask of the same type, thereby reducing photolithography steps.

Accordingly, in the first embodiment, the first p-well region 311 has a doping concentration same as that of the p-well rings 324, the p-type doping region 321 has a doping concentration same as that of the p-plus rings 325, and the p-type junction termination extension region 3221 has a doping concentration same as that of the outer surrounding region 323. In addition, in comparison with the first p-well region 311, the p-well rings 324, the p-type doping region 321, and the p-plus rings 325, the p-type junction termination extension region 3221 and the outer surrounding region 323 have the lowest doping concentration. In some embodiments, the p-well rings 324 have a doping concentration of 1e18 cm⁻³. In still some embodiments, the p-plus rings 325 have a doping concentration of 1e19 cm⁻³. In yet some embodiments, the p-type junction termination extension region 3221 has a doping concentration of 1e17 cm⁻³.

The semiconductor device of the first embodiment, as shown in FIG. 1, is subjected to electrical simulation, and the results of the electrical simulation are shown in FIG. 2. Referring to FIG. 2, when a predetermined concentration ratio of a doping concentration of the p-type junction termination extension region 3221 to a doping concentration of the outer surrounding region 323 ranges from 0.6 to 1.4, a withstand voltage of the semiconductor device is greater than a rated reverse 5 voltage (i.e., a target voltage shown in FIG. 2) of the semiconductor device. In other words, a predetermined breakdown voltage can be achieved within such predetermined concentration ratio, indicating that the semiconductor device with the edge termination region 32 has a very high tolerance for manufacturing errors, which effectively enhances performance and yield of the same.

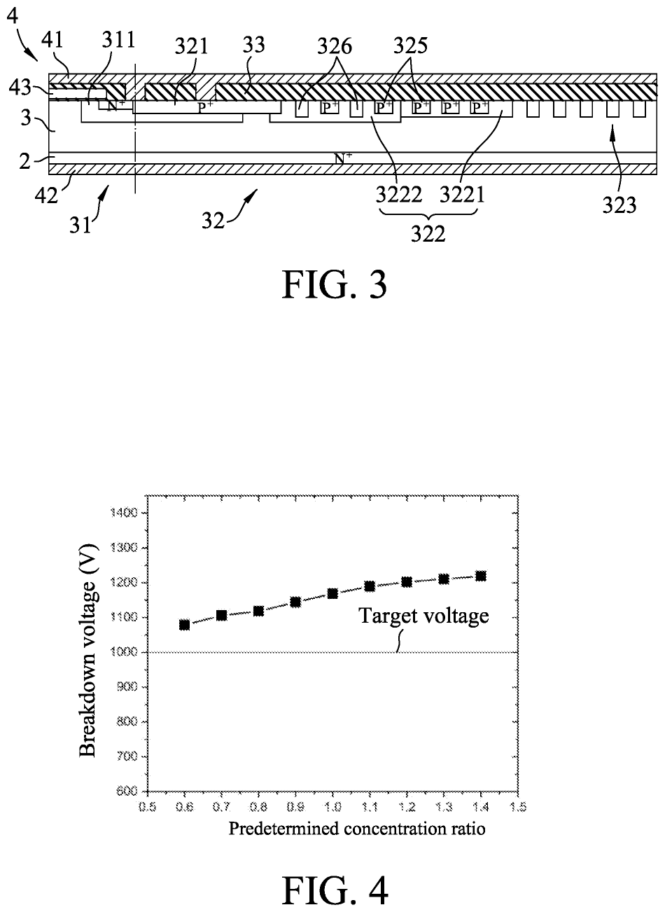

Referring to FIGS. 3 and 4, a second embodiment of the semiconductor device according to the disclosure is generally similar to the first embodiment, except that the p-type extension unit 322 further includes a second p-well region 3222, and that the edge termination region 32 further includes a plurality of p-type junction termination extension (JTE) rings 326 but p-well rings 324 are not included.

To be more specific, the p-type extension unit 322 of the second embodiment includes the p-type junction termination extension region 3221 and the second p-well region 3222 that is disposed between the first p-well region 311 and the p-type junction termination extension region 3221. In addition, the p-plus rings 325 are disposed at intervals in the second p-well region 3222 and the p-type junction termination extension region 3221, and the p-type junction termination extension rings 326 and the p-plus rings 325 in the second p-well region 3222 are alternated with each other. That is to say, both the p-plus rings 325 and the p-type junction termination extension rings 326 are disposed in the p-type extension unit 322, and the p-type junction termination extension rings 326 and some of the p-plus rings 325 are alternated with each other.

The semiconductor device of the second embodiment, as shown in FIG. 3, is subjected to electrical simulation, and the results of the electrical simulation are shown in FIG. 4. Referring to FIG. 4, when a predetermined concentration ratio of a doping concentration of each of the p-type junction termination extension region 3221 and the p-type junction termination extension rings 326 to a doping concentration of the outer surrounding region 323 ranges from 0.6 to 1.4, a withstand voltage of the semiconductor device is greater than a rated reverse voltage (i.e., the target voltage shown in FIG. 4) of the semiconductor device. In other words, a predetermined breakdown voltage can be achieved within such predetermined concentration ratio, indicating that the semiconductor device with the edge termination region 32 has a very high tolerance for manufacturing errors, which effectively enhances performance and yield of the same.

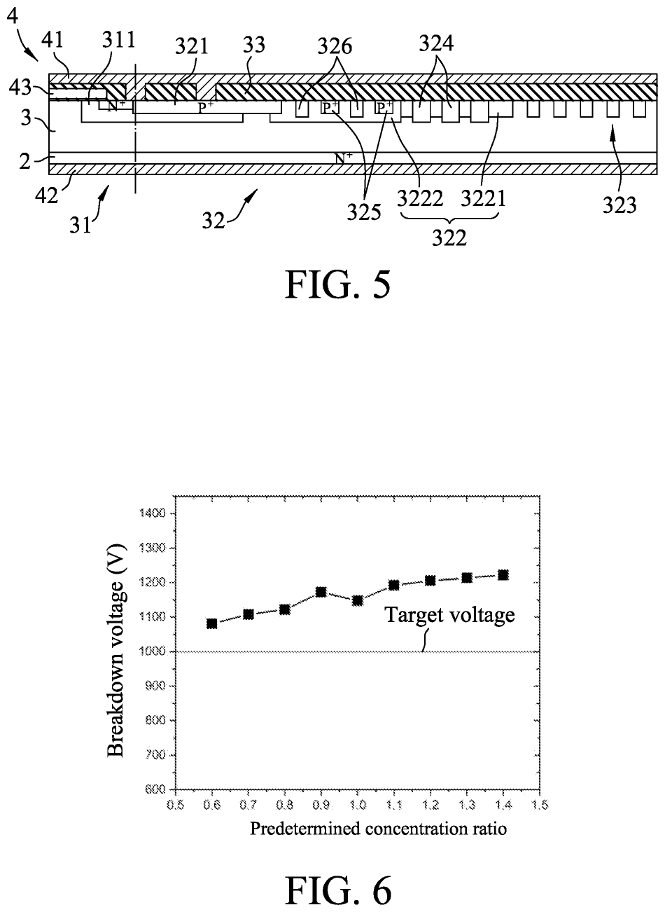

Referring to FIGS. 5 and 6, a third embodiment of the semiconductor device according to the disclosure is generally similar to the second embodiment, except that the edge termination region 32 includes all of the p-well rings 324, the p-plus rings 325, and the p-type junction termination extension rings 326.

To be specific, the p-plus rings 325 and the p-type junction termination extension rings 326 are alternately disposed in the second p-well region 3222, and the p-well rings 324 are disposed at intervals in the p-type junction termination extension region 3221 and protrude from the p-type junction termination extension region 3221, so as to extend an electric field further downwardly. That is to say, the p-well rings 324, the p-plus rings 325, and the p-type junction termination extension rings 326 are disposed in the p-type extension unit 322, and the p-plus rings 325 and the p-type junction termination extension rings 326 are alternated with each other.

The semiconductor device of the third embodiment, as shown in FIG. 5, is subjected to electrical simulation, and the results of the electrical simulation are shown in FIG. 6. Referring to FIG. 6, when a predetermined concentration ratio of a doping concentration of each of the p-type junction termination extension region 3221 and the p-type junction termination extension rings 326 to a doping concentration of the outer surrounding region 323 ranges from 0.6 to 1.4, a withstand voltage of the semiconductor device is greater than a rated reverse voltage (i.e., the target voltage shown in FIG. 6) of the semiconductor device. In other words, a predetermined breakdown voltage can be achieved within such predetermined concentration ratio, indicating that the semiconductor device with the edge termination region 32 has a very high tolerance for manufacturing errors, which effectively enhances performance and yield of the same.

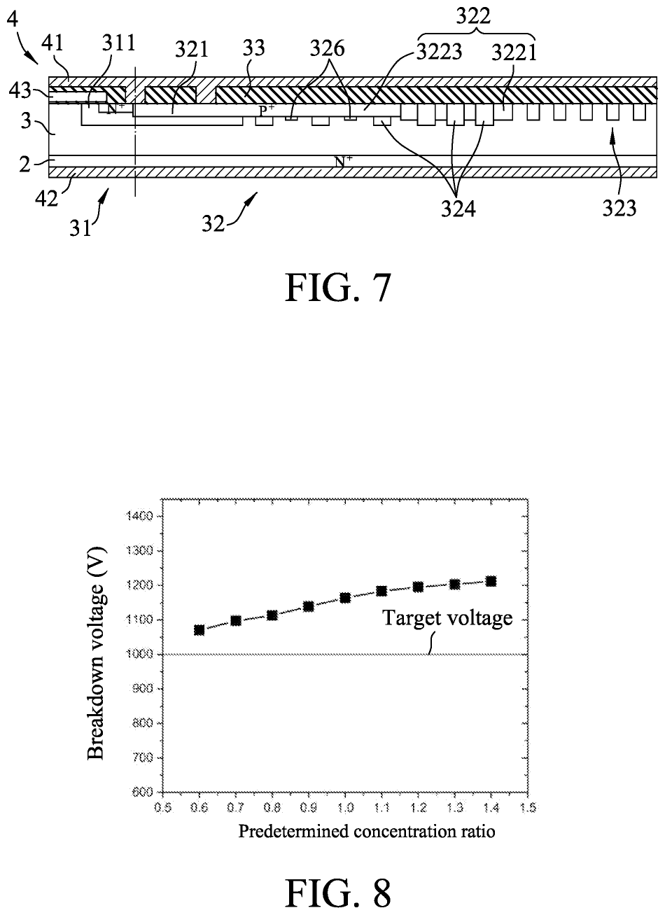

Referring to FIGS. 7 and 8, a fourth embodiment of the semiconductor device according to the disclosure is generally similar to the first embodiment, except that the p-type extension unit 322 further includes a p-type doping extension region 3223 that is connected to the p-type doping region 321, and that the edge termination region 32 includes the p-well rings 324 and the p-type junction termination extension rings 326 but the p-plus rings 325 are not included.

To be specific, the p-type extension region 322 of the fourth embodiment includes the p-type doping extension region 3223 that is connected to the p-type doping region 321, and the p-type junction termination extension region 3221 that is adjacent to the p-type doping extension region 3223. In addition, the p-well rings 324 are disposed at intervals in the p-type doping extension region 3223 and the p-type junction termination extension region 3221, and protrude from the p-type doping extension region 3223 and the p-type junction termination extension region 3221. Moreover, the p-type junction termination extension rings 326 and the p-well rings 324 in the p-type doping extension region 3223 are alternated with each other. That is, the p-well rings 324 and the p-type junction termination extension rings 326 are disposed in the p-type extension unit 322, and the p-type junction termination extension rings 326 and some of the p-well rings 324 are alternated with each other.

The semiconductor device of the fourth embodiment, as shown in FIG. 7, is subjected to electrical simulation, and the results of the electrical simulation are shown in FIG. 8. Referring to FIG. 8, when a predetermined concentration ratio of a doping concentration of each of the p-type junction termination extension region 3221 and the p-type junction termination extension rings 326 to a doping concentration of the outer surrounding region 323 ranges from 0.6 to 1.4, a withstand voltage of the semiconductor device is greater than a rated reverse voltage (i.e., the target voltage shown in FIG. 8) of the semiconductor device. In other words, a predetermined breakdown voltage can be achieved within such predetermined concentration ratio, indicating that the semiconductor device with the edge termination region 32 has a very high tolerance for manufacturing errors, which effectively enhances performance and yield of the same.

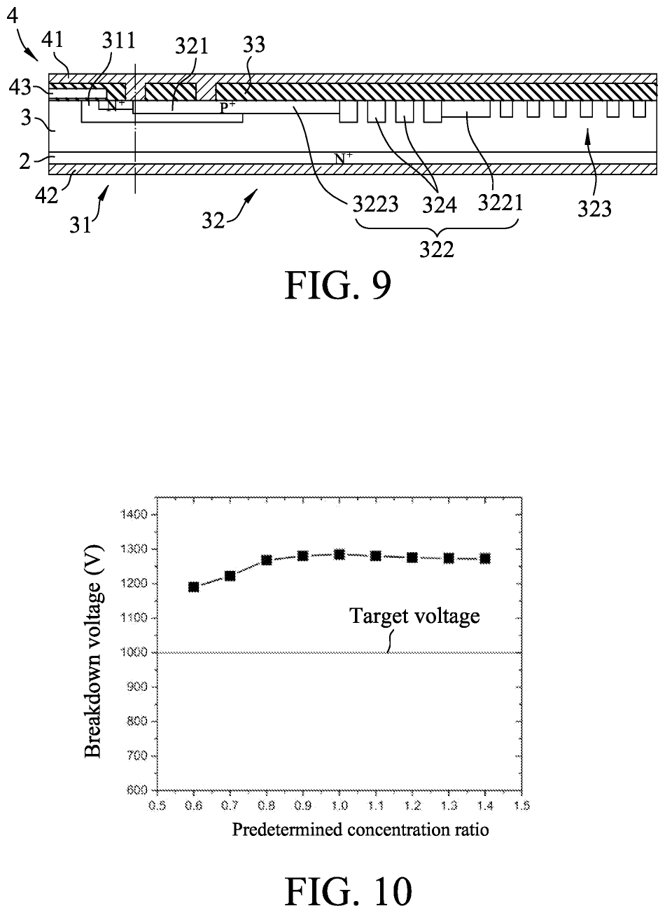

Referring to FIGS. 9 and 10, a fifth embodiment of the semiconductor device according to the disclosure is generally similar to the fourth embodiment, except that the p-type extension unit 322 includes not only the p-type junction termination extension region 3221 and the p-type doping extension region 3223, but also the p-well rings 324, while the p-plus rings 325 and p-type junction termination extension rings 326 are not included in the edge termination region 32. Specifically, the p-well rings 324 are disposed between the p-type doping extension region 3223 and the p-type junction termination extension region 3221, and cooperate with the p-type doping extension region 3223 and the p-type junction termination extension region 3221 to form the p-type extension unit 322. The p-well rings 324 are disposed in the edge termination region 32.

The semiconductor device of the fifth embodiment, as shown in FIG. 9, is subjected to electrical simulation, and the results of the electrical simulation are shown in FIG. 10. Referring to FIG. 10, when a predetermined concentration ratio of a doping concentration of each of the p-type junction termination extension region 3221 and the p-type junction termination extension rings 326 to a doping concentration of the outer surrounding region 323 ranges from 0.6 to 1.4, a withstand voltage of the semiconductor device is greater than a rated reverse voltage (i.e., the target voltage shown in FIG. 10) of the semiconductor device. In other words, a predetermined breakdown voltage can be achieved within such predetermined concentration ratio, indicating that the semiconductor device with the edge termination region 32 has a very high tolerance for manufacturing errors, which effectively enhances performance and yield of the same.

In sum, the semiconductor device including the edge terminal region 32 allows p-type doping to be conducted in a p-type semiconductor, such that p-type columns are directly formed therein, and doping of the edge termination region 32 and doping of the cell trigon can be carried out simultaneously, thereby reducing the number of times required to conduct photolithography, so as to improve yield. Furthermore, by having various types of doping designs in the edge termination region 32, a relatively high breakdown voltage can be expected in the edge termination region 32 having a relatively short width.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor device, comprising:
a substrate;
a main body disposed on said substrate, and including a cell region, an edge termination region that surrounds said cell region, and an oxide insulation layer that is disposed on said cell region and said edge termination region so as to be spaced apart from said substrate, said cell region including a first p-well region, said edge termination region including a p-type extension unit that is adjacent to said first p-well region, an outer surrounding region that surrounds said p-type extension unit, and a p-type doping region that extends from said first p-well region toward said p-type extension unit; and
an electrode unit including a source electrode that is disposed on said oxide insulation layer, a drain electrode that is disposed on said substrate opposite to said main body, and a gate electrode that is disposed in said oxide insulation layer and that corresponds in position to said cell region.

2. The semiconductor device as claimed in claim 1, wherein said edge termination region further includes a plurality of p-well rings and a plurality of p-plus rings that are alternately disposed in said p-type extension unit.

3. The semiconductor device as claimed in claim 1, wherein said edge termination region further includes a plurality of p-plus rings and a plurality of p-type junction termination extension rings that are disposed in said p-type extension unit, said p-type junction termination extension rings and some of said p-plus rings being alternated with each other.

4. The semiconductor device as claimed in claim 1, wherein said edge termination region further includes a plurality of p-well rings, a plurality of p-plus rings, and a plurality of p-type junction termination extension rings that are disposed in said p-type extension unit, said p-plus rings and said p-type junction termination extension rings being alternated with each other.

5. The semiconductor device as claimed in claim 1, wherein said edge termination region further includes a plurality of p-well rings and a plurality of p-type junction termination extension rings that are disposed in said p-type extension unit, said p-type junction termination extension rings and some of said p-well rings being alternated with each other.

6. The semiconductor device as claimed in claim 1, wherein said p-type extension unit includes a plurality of p-well rings that are disposed in said edge termination region.

7. The semiconductor device as claimed in claim 2, wherein said p-type extension unit includes a p-type junction termination extension region, said p-well rings and said p-plus rings being alternately disposed in said p-type junction termination extension region, said p-well rings protruding from said p-type junction termination extension region.

8. The semiconductor device as claimed in claim 3, wherein said p-type extension unit includes a p-type junction termination extension region and a second p-well region disposed between said first p-well region and said p-type junction termination extension region, said p-plus rings being disposed at intervals in said second p-well region and said p-type junction termination extension region, said p-type junction termination extension rings and said p-plus rings in said second p-well region being alternated with each other.

9. The semiconductor device as claimed in claim 4, wherein said p-type extension unit includes a p-type junction termination extension region and a second p-well region disposed between said first p-well region and said p-type junction termination extension region, said p-plus rings and said p-type junction termination extension rings being alternately disposed in said second p-well region, said p-well rings being disposed at intervals in said p-type junction termination extension region, said p-well rings protruding from said p-type junction termination extension region.

10. The semiconductor device as claimed in claim 5, wherein said p-type extension region includes a p-type doping extension region connected to said p-type doping region, and a p-type junction termination extension region adjacent to said p-type doping extension region, said p-well rings being disposed at intervals in said p-type doping extension region and said p-type junction termination extension region and protruding from said p-type doping extension region and said p-type junction termination extension region, said p-type junction termination extension rings and said p-well rings in said p-type doping extension region being alternated with each other.

11. The semiconductor device as claimed in claim 6, wherein said p-type extension region further includes a p-type doping extension region connected to said p-type doping region, and a p-type junction termination extension region being spaced apart from said p-type doping extension region, said p-well rings being disposed between said p-type doping extension region and said p-type junction termination extension region.

12. The semiconductor device as claimed in claim 2, wherein said p-well rings have a doping concentration of 1e18 cm⁻³.

13. The semiconductor device as claimed in claim 2, wherein said p-plus rings have a doping concentration of 1e19 cm⁻³.

14. The semiconductor device as claimed in claim 7, wherein said p-type junction termination extension region has a doping concentration of 1e17 cm⁻³.
